(19) United States
(12) Patent Application Publication
(10) Pub. No.: US 2025/0044712 A1
(43) Pub. Date: Feb. 6, 2025

(54) OPTICAL COMPONENT FOR A LITHOGRAPHY APPARATUS

(71) Applicant: Carl Zeiss SMT GmbH, Oberkochen (DE)

(72) Inventors: Thomas IRTENKAUF, Aalen (DE); Toralf GRUNER, Aalen (DE)

(21) Appl. No.: 18/925,677

(22) Filed: Oct. 24, 2024

Related U.S. Application Data
(63) Continuation of application No. PCT/EP2023/060749, filed on Apr. 25, 2023.

(30) Foreign Application Priority Data
Apr. 29, 2022 (DE) 10 2022 204 268.9

(51) Int. Cl. G03F 7/00; G02B 27/00; G03F 7/20

(52) U.S. Cl. CPC G03F 7/7095; G03F 7/2004; G03F 7/70033; G03F 7/70225; G03F 7/70825; G03F 7/70975; G02B 27/0012

(57) ABSTRACT

An optical component (100, 200) for a lithography apparatus (1) includes an optical element (102, 202), produced from a first material (G₁₀₂) and having an optically effective surface (106, 206); and a carrying element (104, 204), produced from a second material (G₁₀₄) and carrying the optical element (102, 202). The second material (G₁₀₄) differs from the first material (G₁₀₂) and a ratio of the densities of the first and second materials (G₁₀₂, G₁₀₄) deviates from 1 by less than 20%, preferably by less than 10% or even less than 5%. The optical element and the carrying element each have principal extension planes (H₁₀₂, H₂₀₂, H₁₀₄, H₂₀₄) having maximum extents. The maximum extent (D₁₀₂, A₂₀₂) of the optical element (102, 202) is less than 90%, preferably less than 80% or even less than 75% of the maximum extent (A₁₀₄, D₂₀₄) of the carrying element.

### CROSS REFERENCE TO RELATED APPLICATIONS

This is a Continuation of International Application PCT/EP2023/060749, which has an international filing date of Apr. 25, 2023, and which claims the priority of German Patent Application 10 2022 204 268.9, filed Apr. 29, 2022. The disclosures of both applications are incorporated in their respective entireties into the present Continuation by reference.

### FIELD OF THE INVENTION

The present invention relates to an optical component, a use of an optical component, a projection lens, a lithography apparatus and a plurality of methods for producing such an optical component.

### BACKGROUND

Microlithography is used to produce microstructured component parts, for example integrated circuits. The microlithography process is carried out using a lithography apparatus comprising an illumination system and a projection system. The image of a mask (reticle) illuminated with the illumination system is projected here with the projection system onto a substrate, for example a silicon wafer, which is coated with a light-sensitive layer (photoresist) and arranged in the image plane of the projection system, in order to transfer the mask structure to the light-sensitive coating of the substrate.

Driven by the desire for ever smaller structures in the production of integrated circuits, extreme ultraviolet (EUV) lithography apparatuses that use light with a wavelength in the range from 0.1 nm to 30 nm, in particular 13.5 nm, are currently under development. Since most materials absorb light of this wavelength, it is necessary in such EUV lithography apparatuses to use reflective optics, i.e., mirrors, instead of—as previously—refractive optics, i.e., lens elements.

Besides dispensing with refractive media, taking the step to the EUV range also means a transition to mirror systems that operate with either almost normal incidence or grazing incidence. With normal incidence, approximately a third of the incident light is absorbed on each mirror (depending on the specific incidence angle spectrum); with grazing incidence, typical absorption values are a quarter or a fifth. By contrast, in refractive media, such as lens elements, with an antireflection layer, the absorbed intensity, for comparison, is in the per mille range. This explains considerably greater temperature changes in EUV optics in comparison with systems based on lens elements. The temperature changes are in the range of several kelvins, instead of a few tenths of a kelvin as in lens element systems.

Since temperature gradients are translated into surface defects on account of the coefficient of thermal expansion, their consequence, precisely in mirrors, is considerable optical aberrations that cause images to deteriorate in relation to the used wavelength. Accordingly, EUV mirrors are preferably fabricated from materials having particularly low coefficients of thermal expansion, for example from Zerodur® or ULER (“ultralow expansion” material). These materials play off component parts having respective positive and negative coefficients of thermal expansion against one another. The result is an effectively linear relationship between thermal expansion and temperature, where there is exactly one temperature value at which the thermal expansion vanishes, namely at the so-called zero-crossing temperature. Such materials are particularly complicated to produce and therefore expensive. Accordingly, the optical units produced therefrom are likewise cost-intensive. In actual fact, these costs are one of the major obstacles on the way to increasing the numerical aperture, which requires the use of larger mirrors, that is to say having a larger diameter. The higher material costs also have a particularly limiting effect since, as the mirror diameter increases, the thickness of the mirror must also be increased in order to limit dynamically generated deformations.

### SUMMARY

Against this background, it is an object of the present invention to provide an improved optical component for a lithography apparatus.

Accordingly, an optical component for a lithography apparatus is proposed. According to one formulation, this optical component comprises an optical element, which is fabricated from a first material and comprises an optically effective surface. Furthermore, the optical component comprises a carrying element, which is fabricated from a second material and carries the optical element. The second material differs from the first material. The ratio of the densities of the first and second materials deviates from 1 by less than 20%, preferably by less than 10%, and even more preferably by less than 5%. The optical element and the carrying element each have a principal extension plane, in which they have a maximum extent. The maximum extent of the optical element is less than 90%, preferably less than 80%, and even more preferably less than 75%, of the maximum extent of the carrying element.

One insight associated with the present invention is that the carrying element fulfills functionally different tasks than the optical element and can therefore be fabricated from a different, in particular cost-effective, material. Nevertheless, the carrying element or the second material thereof should be as similar as possible to the first material (albeit more cost-effective). Accordingly, a mechanical and/or thermal behavior of the carrying element can be approximated to that of the optical element. A negative mechanical interaction between the optical element and the carrying element can be minimized as a result. The optical element having a smaller maximum extent than the carrying element (in each case in relation to their principal extension plane) ensures that the carrying element can support the optical element over a large area.

The principal extension plane of the optical element and the principal extension plane of the carrying element are preferably arranged parallel to one another or are at an angle to one another of less than 10 degrees, preferably less than 5 degrees, and even more preferably less than 3 degrees.

In the present case, the “optically effective surface” is taken to mean that surface of the optical element which interacts with the used light (operating light), in particular for the imaging process.

The optical component is designed in a suitable manner in particular for use in the field of lithography. It can be used therein for instance for lithography apparatuses (deep ultraviolet (DUV) and EUV), measuring instruments or production apparatuses.

In accordance with one embodiment, the optical element and the carrying element each comprise a maximum thickness perpendicular to the principal extension plane, wherein the maximum thickness of the optical element is less than 90%, preferably less than 80%, even more preferably less than 75%, of the maximum thickness of the carrying element.

This advantageously ensures that the carrying element can absorb the majority of the deformation forces which act on the optical component—for example in the context of a manipulation during operation of the lithography apparatus.

In accordance with a further embodiment, the optical element comprises a side facing away from the optically effective surface, wherein the side comprises a side surface and at least 50%, preferably at least 75%, even more preferably at least 90%, of the side surface of the optical element or the entirety thereof is in, preferably whole-area, contact with the carrying element.

This measure, too, improves a force input from the carrying element into the optical element, and vice versa. A point contact between the optical element and the carrying element can be sufficient, in principle. However, a whole-area contact between the side surface (for example over at least 90% thereof) and the carrying element is preferred since point deformations can be better avoided in this way. The entirety thereof being in contact means that 100% of the side surface is in contact with the carrying element. This precludes somewhat the presence of cooling channels at the interface between the optical element and the carrying element.

In accordance with a further embodiment, the optical element is accommodated in a depression, in particular in a pot-shaped depression, or in a through opening in the carrying element.

This measure, too, makes it possible to improve a force coupling between the optical element and the carrying element.

In accordance with a further embodiment, a material boundary between the first and second materials runs partly or completely in a direction perpendicular to the principal extension plane of the optical element.

In particular, the optical element can be connected to the carrying element both at the rear side of the optical element and at one or more circumferential surfaces running perpendicular thereto (or at a different angle other than perpendicular). The force coupling is improved thereby too.

In accordance with a further embodiment, the optical element and the carrying element are formed integrally with one another.

That is to say that the optical element and the carrying element are connected to one another fixedly, that is to say immovably, in six degrees of freedom.

In accordance with a further embodiment, the optical element and the carrying element are secured to one another in a force-locking, materially bonded and/or interlocking manner.

“Force-locking engagement” is taken to mean a frictional connection or a connection with the aid of magnetic forces. In the case of “frictional engagement”, a normal force acts perpendicularly on the surfaces of the optical element and of the carrying element which provide the frictional engagement and bare against one another. “Materially bonded engagement” is taken to mean a connection with the aid of adhesion forces. This can be done with the aid of an adhesion-promoting material, such as adhesive, for example, or else without such material. In the latter case, the optical element and the carrying element adhere directly to one another. This is done by wringing or fusion, for example. An “interlocking engagement” is taken to mean the connection partners mutually engaging behind one another. That is to say that the optical element and the carrying element engage behind one another at one or more securing points. For this purpose, provision is made of an engagement mechanism and a receiving mechanism, for example, or alternatively provision can be made of an additional connection mechanism (separate part), which interlockingly connects the optical element and the carrying element to one another. In this case, the securing mechanism comprises either the engagement mechanism or the receiving mechanism. The optical element and the carrying element comprise a corresponding receiving or engagement mechanism in this case. The connection mechanism then interlockingly connects the optical element and the carrying element. In the case of the force-locking or materially bonded engagement, too, a securing mechanism (separate part) can be used (indirect securing).

In accordance with a further embodiment, the optical element and the carrying element are fused together, adhesively bonded to one another or wrung on one another.

Such a connection technique is advantageous because it ensures a uniform force transmission over the surface.

Furthermore, the following methods (also in combination with one another) are feasible for connecting the optical element and the carrying element to one another, where methods of materially bonded engagement, in particular, may be involved:
Glass frit bonding (soldering using glass solder). This connection is advantageously inorganic and may have a melting point of between 30° and 400° C., for example.
Soldering, in particular using metallic solders. This kind of connection is advantageously inorganic. In particular, low melting point solders having a melting point of, for example, 60-400° C., preferably 60-250° C., can be used. Particularly preferably, a solder having a melting point of greater than 200° C. is used.
Diffusion-driven methods, such as, for example, thermocompression bonding, solid-liquid interdiffusion bonding and/or eutectic joining.
Welding, in particular:

Beam-based welding, such as laser welding, for example. The following procedure may be chosen for this purpose: polishing the surfaces of the components to be joined (here: optical element and/or carrying element), wringing components on one another, focusing lasers in the region of the joining surfaces and melting partial regions and thereby connecting the components.

Friction welding, possibly in conjunction with a metallic coating.

Cold welding methods, in particular diffusion-driven connection processes, for example accelerated by an increased temperature or an increased joining pressure. In this respect, the following method, in particular, may be chosen: Firstly, the surfaces of the components to be joined (here: optical element and/or carrying element) are polished and then the components are wrung on one another. Afterward, the components rest until the material exchange in the connection surfaces results in the desired strength.
Silicate-based joining and/or hydroxide-based joining, especially for silicon-containing materials.
Reactive joining.
Anodic bonding.
Surface-activated bonding, in particularly using a metallic coating.

In accordance with a further embodiment, the first and second materials differ in one or more of the following properties: a refractive index homogeneity; a proportion and/or a size of inclusions, in particular bubbles; a stress birefringence; an intrinsic polarization birefringence; a transmissivity, particularly at the operating wavelength of the optical element; a density and/or a change in the density in at least one spatial direction; a hardness or a change in the hardness in at least one spatial direction; a roughness; a slumping property; and a resistance to compaction and/or solarization.

Advantageously, differences between the first and second materials are permitted in regard to these properties, whereby the production costs for the second material are reduced. In specific detail, the properties can be defined as follows:

Ascertaining the refractive index homogeneity involves the following procedure: Both for the optical element and for the carrying element (which are designed as refractive optical units in this case), a refractive index distribution over the respective volume thereof is ascertained. Afterward, one or more variables characterizing the variation of the refractive index over the volume are ascertained. Such a variable is e.g. a peak-valley value, an RMS value (“root mean square”) or an expansion coefficient of a fit of one or more profile functions to the measured distribution. The profile functions can be, in particular, products of Legendre polynomials or

Zernike functions. The one or more characterizing variables of the optical element are subsequently compared with that or those of the carrying element. A “homogeneity” in the present sense is present for example when the ratio of the variables characterizing the variation or the largest of the respective ratios for a plurality of such variables is less than 150%. The refractive index, also referred to as index of refraction, should be understood to mean the ratio of co, the speed of light in vacuum, to CM, the speed of propagation of light in the respective medium (i.e. the first or second material).

The proportion of inclusions in the first or second material can be expressed as percent by volume. The size of the inclusions can be specified as the largest dimension, for example the largest diameter. By way of example, the largest bubble in the first material can be compared with the largest bubble in the second material, a maximum diameter thereof being taken into account in each case. The difference in the proportion by volume and/or in the size of inclusions can be for example greater than 5%, greater than 10% or greater than 20%.

The stress birefringence can be determined by detecting a loss of contrast of light which passes through the first or respectively second material. The loss of contrast is the result of the change in the polarization direction. The loss of contrast can be specified in nanometers per centimeter. By way of example, a difference in the maximum value of the stress birefringence between the first and second materials can be 0.2 nm/cm, 0.5 nm/cm or 1.0 nm/cm.

By way of example, the intrinsic polarization birefringence of the first material can correspond to that of a calcium fluoride crystal or lie within a tolerance window according to a predefined accuracy of the crystal orientation around a predefined value. The tolerance window can be for example −5°, −10°, −20° to 5°, 10°, 20°. By way of example, the crystal orientation in the calcium fluoride crystal can be 100, 111 or 110. By contrast, the second material has no intrinsic birefringence.

Likewise, both materials can have an intrinsic polarization birefringence, wherein the deviation of this birefringence in the first material is less than 0.1 nm/cm, 0.2 nm/cm or 0.5 nm/cm from a designed value for this intrinsic birefringence or the true crystal orientation deviates by less than 5°, 10° or 20° from a designed value for the crystal orientation, while the deviation in the second material is correspondingly higher, e.g. in each case by at least 20% or 50%. This deviation can be caused by a setting of varying precision for the true crystal orientation angle relative to a predefined angle in the respective material.

In the present case, the transmissivity k is defined as the ratio of Iₑᵢₙ, the quantity of light incident on the optical element or respectively the carrying element, to Iᵥₑᵣ, the quantity of light leaving the optical element or respectively the carrying element, wherein the ratio is specified as:

$${I}_{ver} = {e}^{- kL} {I}_{ein}$$

where “L” describes the distance in the first or respectively second material traversed by the incident light. The distance is specified in meters, for example. The difference in transmissivity between the optical element and the carrying element is for example greater than 5%, greater than 10% or greater than 20%.

The density, expressed as mass per volume, or the change therein, that is to say the gradient in a spatial direction, of the first material preferably deviates from the density or change therein of the second material by greater than 5%, greater than 10% or greater than 20%.

In the present case, a “slumping property” is understood to mean the following: The optical element, but also the carrying element (although less preferably) can have a layered construction. In this case, in the context of production, a blank of layered construction is passed into or onto a curved mold and heated there. Accordingly, the layer stack (in a deformable state courtesy of the high temperature) also uniformly assumes the corresponding shape, wherein the layer sequence is largely preserved along the surface normals. A high-quality component can be created by this method. In particular, it is thereby possible to produce the optical component with the desired curvature at its optically effective surface. A difference between the first and second materials with regard to the slumping property thereof can either consist in the fact that the first material or the optical element has been produced in a slumping method, as described above, and the second material or the carrying element was not produced in such a method. Insofar as both the first and second materials (or optical element and carrying element) have been produced in a slumping method, the thicknesses of the layer sequence along the surface normals may differ to varying extents from a desired target state. In particular, the layer thickness accuracies of the first material or of the optical element, on average or as a maximum, can be closer than 10%, closer than 25% or closer than 50% to a predefined value in comparison with the layer thickness accuracies of the second material or of the carrying element with respect to said predefined value, likewise on average or as a maximum.

In order to strengthen quartz glass or other materials vis-à-vis compaction and solarization on account of bonds being broken by the high-energy used radiation (operating light), loading with hydrogen or a comparable pretreatment can be effected, which is often time-consuming. Accordingly, an irradiation of the (suitably selected and/or treated) first material with a predetermined number of LASER pulses can lead to a change in refractive index or transmission that is lower by 50%, preferably 80%, more preferably 90%, in comparison with the second material, an identical test specimen and irradiation geometry being present. In particular, the time for loading the first material with hydrogen can be at least 50%, 100% or 200% greater than that for the second material.

The roughness of the surface of the optical element in a spatial frequency range of 10 nm-1 mm can be characterized by an RMS value which is less than that of the carrying element by a factor of 5, 10 or 20 or more, and in particular can be less than 0.5 nm, 0.3 nm or 0.1 nm. Corresponding ratios of the RMS values can also be present in each case in individual bands for spatial frequencies, for instance in the band 100 μm-1 mm, 10 μm-100 μm, 1 μm-10 μm or 100 nm-1 μm.

In accordance with a further embodiment, at an expectable mean operating temperature, a coefficient of thermal expansion of the first material is at least ten times lower than a coefficient of thermal expansion of the second material.

This also ensures that the first material is of higher quality than the second material. The expectable mean operating temperature depends on the purpose of use of the optical component.

In accordance with a further embodiment, the carrying element comprises one or more of the following component parts: a mechanical interface for securing said carrying element to a carrying frame of a lithography apparatus and/or for securing an actuator, and/or a measurement object for measuring the position of the carrying element with the aid of a measuring device.

The carrying element is thus required to have specific functions which deviate from those of the optical element, which itself comprises the optically effective surface (function of the optical element).

In accordance with a further embodiment, the optical element is a mirror, a lens element, a polarization-optical element, in particular a retarder plate, a polarization filter or a rotation element configured to rotate a polarization direction, a color filter and/or an optical grating.

In accordance with a further embodiment, the first material is ultralow expansion material (ULE®), Zerodur®, calcium fluoride and/or quartz glass, and/or the second material is quartz glass, optical glass, glass ceramic, silicon, SiSiC or steel, in particular Invar®.

Accordingly, the first material is of optically higher quality than the second material, and the second material is more cost-effective in return. ULE is a titanium-doped quartz glass. Zerodur is a glass ceramic. Invar is an iron-nickel alloy comprising an iron proportion of 64% and a nickel proportion of 36%. SiSiC is a silicon carbide.

In accordance with a second aspect, a use of the optical component as described above is provided. In this case, the optical component is used in an imaging process, wherein a used operating light comprises a wavelength of less than 120 nm, preferably 30 nm. The operating light interacts with the optically effective surface of the optical element.

In accordance with a third aspect, a projection lens, in particular a catadioptric projection lens or with a pure mirror system, is provided. The projection lens comprises an optical component as described above.

In particular, the optical element of the component can be a lens element arranged near-field or intermediately in the beam path. Alternatively, the component is a mirror or some other optical element.

In accordance with a fourth aspect, a lithography apparatus, in particular an EUV or DUV lithography apparatus, is provided. This apparatus comprises the optical component as described above or a projection lens as described above.

EUV stands for “extreme ultraviolet” and denotes a wavelength of the operating light of between 0.1 nm and 30 nm. DUV stands for “deep ultraviolet” and denotes a wavelength of the operating light of between 30 nm and 250 nm.

In accordance with a fifth aspect, a method for producing an optical component as described above is provided. The method comprises the following steps:
a) simulating properties of the optical component in operation;
b) adapting at least one of these properties depending on the simulation; and
c) producing the optical component with the adapted property.

This method is based on the consideration that the use of the first (expensive) material and of the second (more cost-effective) material is adapted to the relevant use scenarios.

In accordance with a further embodiment, the properties of the optical component in operation are simulated in accordance with step a) in a first simulation. In a further step, a production outlay for producing the optical component is simulated in a second simulation. Afterward, adapting the at least one property in accordance with step b) is effected depending on the first and second simulations.

The production outlay can be expressed for example in machine hours, material costs, etc. As a result, a solution that is suitable both from an optical standpoint and in relation to production costs is ascertained in a simple manner.

In accordance with a further embodiment, the properties simulated in accordance with step a) comprise an optical property of the optically effective surface. The optical property is for example a thermal expansion, a refractive index, a surface deformation or an imaging aberration, including across the projection lens or the lithography apparatus. This is therefore taken to mean, in particular, an imaging aberration on a wafer to be exposed.

In accordance with a further embodiment, adapting the at least one property in accordance with step b) comprises adapting a dimension of the optical element and/or of the carrying element and/or adapting the first or second material.

If it is thus established that, for example, the optical property does not yet satisfy the requirements, then the optical element, for example, can be made larger (in particular with a larger volume). Additionally or alternatively, an optically better first material can be used.

In accordance with a further embodiment, a correction mechanism is ascertained for adapting the at least one property of the optical element, wherein the correction mechanism is provided outside the optical component.

Advantageously, the desired optical property can be attained not just by adapting the optical element or respectively the carrying element. Rather, correction a mechanism that are known—in particular from the prior art—can be used in order (nevertheless) to be able to use a smaller optical element or an optical element composed of a first material of lesser quality.

In accordance with a sixth aspect, a method for producing an optical component for a lithography apparatus is provided. Said method comprises the following steps:
a) fabricating an optical element made from a first material comprising an optically effective surface; and
b) fabricating a carrying element made from a second material, wherein the second material differs from the first material and a ratio of the densities of the first and second materials deviates from 1 by less than 20%, preferably by less than 10%, and even more preferably by less than 5%;
c) connecting the optical element to the carrying element such that the carrying element carries the optical element, wherein the optical element and the carrying element each have a principal extension plane, in which they have a maximum extent, wherein the maximum extent of the optical element is less than 90%, preferably less than 80%, and even more preferably less than 75%, of the maximum extent of the carrying element.

Steps a) to c) can be carried out in any order, in principle. For instance, it is possible firstly to fabricate the carrying element and directly afterward to produce the optical element, i.e. steps a) and c) are effected simultaneously and after step b).

In accordance with one embodiment, in step a) a variation of an ablation rate at which the first material is ablated is greater than 20%. Alternatively or additionally, in step b) a variation of an ablation rate at which the second material is ablated is less than or equal to 20%.

The higher the variation of the ablation rate, the greater the processing outlay. By way of example, the ablation rate varies if different crystal structures or planes each have to be ablated with high quality—for instance in the case of carving a curved shape made from calcium fluoride. If the intention is to attain a suitable refractive index for lens elements, for instance, then a correspondingly large variation of the ablation rate (for instance greater than 20%) may be necessary. On the other hand, a carrying element can be fabricated cost-effectively with only a small variation of the ablation rate (for instance less than 20%). The ablation rate is expressed for example as mm3/h (that is to say material volume ablated per unit time). The variation relates for example to the entire fabrication process from the material blank to the (finished) optical element or carrying element. The ablation rate can relate to ablation by means of milling or polishing, for example.

In accordance with a further embodiment, the fabricating in step a) and/or step b) comprises the application of a slumping method, wherein preferably a maximum or mean deviation of an actual layer thickness from a target layer thickness is smaller for the first material than for the second material.

Accordingly, the first material is of higher quality than the second material, which can be fabricated more cost-effectively in return.

“A (n); one” in the present case should not necessarily be understood as restrictive to exactly one element. Rather, a plurality of elements, such as two, three or more, can also be provided. Nor should any other numeral used here be understood to the effect that there is a restriction to exactly the stated number of elements. Rather, unless indicated otherwise, numerical deviations upward and downward are possible.

The embodiments and features described for the first aspect apply, mutatis mutandis, to the other aspects, and vice versa.

Further possible implementations of the invention also encompass not explicitly mentioned combinations of features or embodiments that are described above or hereinafter with respect to the exemplary embodiments. In this case, a person skilled in the art will also add individual aspects as improvements or supplementations to the respective basic form of the invention.

Further advantageous configurations and aspects of the invention are the subject matter of the dependent claims and also of the exemplary embodiments that are described below. Aspects of the invention are explained in greater detail hereinafter on the basis of preferred embodiments with reference to the accompanying Figures.

The embodiments and features described for the first aspect correspondingly apply, mutatis mutandis, to the further aspects described in the present case, and vice versa.

### BRIEF DESCRIPTION OF THE DRAWINGS

FIG. 1 shows a schematic meridional section of a projection exposure apparatus for EUV projection lithography;

FIG. 2 shows a perspective view of a detail from a lithography apparatus in accordance with one embodiment;

FIG. 3 shows a partial section III from FIG. 2;

FIG. 4 shows as a detail a plan view IV from FIG. 2;

FIG. 5 shows a view V from FIG. 4;

FIG. 6 shows a section through an optical component in accordance with a further embodiment;

FIG. 7 shows a section through an optical component in accordance with yet another embodiment;

FIG. 8 shows a section through an optical component in accordance with yet another embodiment;

FIG. 9 shows a section through an optical component in accordance with yet another embodiment;

FIG. 10 shows a side view of an optical component with a lens element in accordance with one embodiment;

FIG. 11 shows a view XI from FIG. 10;

FIG. 12 shows a flow diagram of a method in accordance with one embodiment;

FIG. 13 shows a method step in a slumping method;

FIG. 14 shows a view XIV from FIG. 13; and

FIG. 15 shows a flow diagram of a method in accordance with one embodiment.

### DETAILED DESCRIPTION

Unless indicated otherwise, elements that are identical, analogous or functionally identical or analogous have been provided with the same reference signs in the Figures. Furthermore, it should be noted that the illustrations in the Figures are not necessarily true to scale.

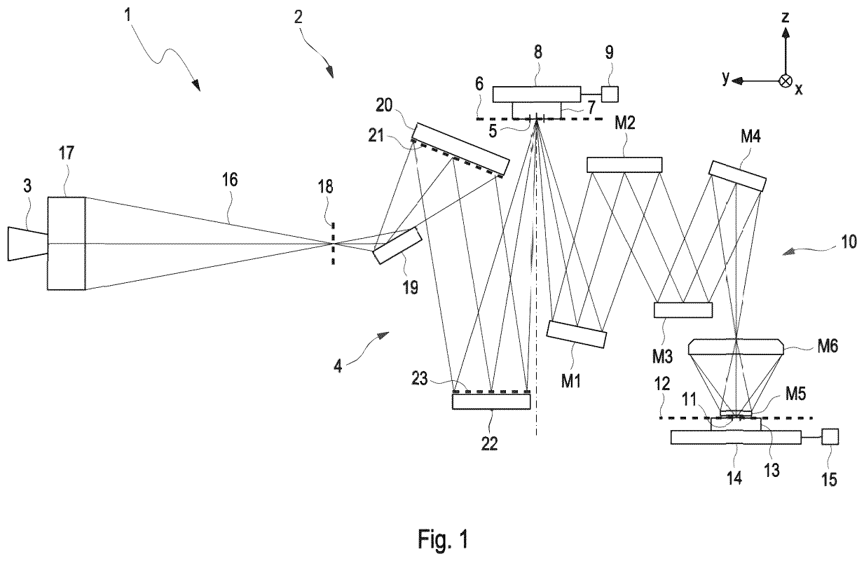

FIG. 1 shows one embodiment of a projection exposure apparatus 1 (lithography apparatus), in particular an EUV lithography apparatus. One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 can also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable with a reticle displacement drive 9, in particular in a scanning direction.

FIG. 1 shows, for explanatory purposes, a Cartesian coordinate system with an x-direction x, a y-direction y and a z-direction z. The x-direction x runs perpendicularly into the plane of the drawing. The y-direction y runs horizontally, and the z-direction z runs vertically. The scanning direction in FIG. 1 runs along the y-direction y. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. As an alternative, an angle that differs from 0° between the object plane 6 and the image plane 12 is also possible.

A structure on the reticle 7 is imaged on a light-sensitive layer of a wafer 13 arranged in the region of the image field 11 in the image plane 12. The wafer 13 is held by a wafer holder 14. The wafer holder 14 is displaceable with a wafer displacement drive 15, in particular in the y-direction y. The displacement firstly of the reticle 7 with the reticle displacement drive 9 and secondly of the wafer 13 with the wafer displacement drive 15 can be implemented so as to be mutually synchronized.

The light source 3 is an EUV radiation source. The light source 3 emits in particular EUV radiation 16, which is also referred to below as used radiation, illumination radiation or illumination light. In particular, the used radiation 16 has a wavelength in the range between 5 nm and 30 nm. The light source 3 can be a plasma source, for example an LPP (short for: laser produced plasma) source or a DPP (short for: gas-discharge produced plasma) source. It can also be a synchrotron-based radiation source. The light source 3 can be an FEL (short for: free-electron laser).

The illumination radiation 16 emanating from the light source 3 is focused by a collector 17. The collector 17 can be a collector with one or more ellipsoidal and/or hyperboloidal reflection surfaces. The at least one reflection surface of the collector 17 can be impinged upon by the illumination radiation 16 with grazing incidence (abbreviated as: GI), which is to say with angles of incidence greater than 45°, or with normal incidence (abbreviated as: NI), which is to say with angles of incidence less than 45°. The collector 17 can be structured and/or coated, firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 can represent a separation between a radiation source module, comprising the light source 3 and the collector 17, and the illumination optical unit 4.

The illumination optical unit 4 comprises a deflection mirror 19 and, arranged downstream thereof in the beam path, a first facet mirror 20. The deflection mirror 19 can be a plane deflection mirror or, alternatively, a mirror with a beam-influencing effect that goes beyond the purely deflecting effect. Alternatively or additionally, the deflection mirror 19 can be embodied as a spectral filter separating a used light wavelength of the illumination radiation 16 from extraneous light having a wavelength that deviates therefrom. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which can also be referred to as field facets. Only some of these first facets 21 are shown in FIG. 1 by way of example.

The first facets 21 can be embodied as macroscopic facets, in particular as rectangular facets or as facets with an arcuate or part-circular edge contour. The first facets 21 can be in the form of plane facets or alternatively in the form of convexly or concavely curved facets.

As known for example from DE 10 2008 009 600 A1, the first facets 21 themselves can also be composed in each case of a multiplicity of individual mirrors, in particular a multiplicity of micromirrors. The first facet mirror 20 can in particular be designed as a microelectromechanical system (MEMS system). For details, reference is made to DE 10 2008 009 600 A1.

The illumination radiation 16 propagates horizontally, i.e. along the y-direction y, between the collector 17 and the deflection mirror 19.

In the beam path of the illumination optical unit 4, a second facet mirror 22 is disposed downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can, for example, have a round, rectangular or else hexagonal boundary, or alternatively be facets composed of micromirrors. In this regard, reference is likewise made to DE 10 2008 009 600 A1.

The second facets 23 can have plane reflection surfaces or, alternatively, convexly or concavely curved reflection surfaces.

The illumination optical unit 4 consequently forms a doubly faceted system. This fundamental principle is also referred to as a fly's eye condenser (or fly's eye integrator).

It may be advantageous to arrange the second facet mirror 22 not exactly in a plane that is optically conjugate to a pupil plane of the projection optical unit 10. In particular, the second facet mirror 22 can be arranged so as to be tilted in relation to a pupil plane of the projection optical unit 10, as is described for example in DE 10 2017 220 586 A1.

With the aid of the second facet mirror 22, the individual first facets 21 are imaged into the object field 5. The second facet mirror 22 is the last beam-shaping mirror or actually the last mirror for the illumination radiation 16 in the beam path upstream of the object field 5.

In a further embodiment (not illustrated) of the illumination optical unit 4, a transfer optical unit contributing in particular to the imaging of the first facets 21 into the object field 5 can be arranged in the beam path between the second facet mirror 22 and the object field 5. The transfer optical unit can have exactly one mirror or, alternatively, two or more mirrors, which are arranged in succession in the beam path of the illumination optical unit 4. The transfer optical unit can in particular comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20, and the second facet mirror 22.

In a further embodiment of the illumination optical unit 4, the deflection mirror 19 can also be omitted, and so the illumination optical unit 4 can then have exactly two mirrors downstream of the collector 17, specifically the first facet mirror 20 and the second facet mirror 22.

The imaging of the first facets 21 into the object plane 6 with the second facets 23 or using the second facets 23 and a transfer optical unit is routinely only approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are likewise possible. The projection optical unit 10 is a doubly obscured optical unit. The penultimate mirror M5 and the last mirror M6 each have a passage opening for the illumination radiation 16. The projection optical unit 10 has an image-side numerical aperture that is greater than 0.5 and can also be greater than 0.6 and can be for example 0.7 or 0.75.

Reflection surfaces of the mirrors Mi can be in the form of freeform surfaces without an axis of rotational symmetry. Alternatively, the reflection surfaces of the mirrors Mi can be in the form of aspherical surfaces with exactly one axis of rotational symmetry of the reflection surface shape. Just like the mirrors of the illumination optical unit 4, the mirrors Mi can have highly reflective coatings for the illumination radiation 16. These coatings can be designed as multilayer coatings, in particular with alternating layers of molybdenum and silicon.

The projection optical unit 10 has a large object-image offset in the y-direction y between a y-coordinate of a center of the object field 5 and a y-coordinate of the center of the image field 11. This object-image offset in the y-direction y can be of approximately the same magnitude as a z-distance between the object plane 6 and the image plane 12.

In particular, the projection optical unit 10 can have an anamorphic design. It has in particular different imaging scales βx, βy in the x- and y-directions x, y. The two imaging scales βx, βy of the projection optical unit 10 are preferably (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, i.e. in a direction perpendicular to the scanning direction.

The projection optical unit 10 leads to a reduction in size of 8:1 in the y-direction y, i.e. in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 can be the same or can differ, depending on the embodiment of the projection optical unit 10. Examples of projection optical units with different numbers of such intermediate images in the x-direction x and y-direction y are known from US 2018/0074303 A1.

In each case, one of the second facets 23 is assigned to exactly one of the first facets 21 for forming in each case an illumination channel for illuminating the object field 5. This can in particular result in illumination according to the Köhler principle. The far field is decomposed into a multiplicity of object fields 5 with the aid of the first facets 21. The first facets 21 create a plurality of images of the intermediate focus on the second facets 23 respectively assigned to them.

Through an assigned second facet 23, the first facets 21 are in each case imaged onto the reticle 7 in a manner overlaid on one another for the purpose of illuminating the object field 5. The illumination of the object field 5 is in particular as homogeneous as possible. It preferably has a uniformity error of less than 2%. Field uniformity can be attained by overlaying different illumination channels.

The illumination of the entrance pupil of the projection optical unit 10 can be defined geometrically by an arrangement of the second facets 23. The intensity distribution in the entrance pupil of the projection optical unit 10 can be set by selecting the illumination channels, in particular the subset of the second facets 23, which guide light. This intensity distribution is also referred to as illumination setting or illumination pupil filling.

A likewise preferred pupil uniformity in the region of portions of an illumination pupil of the illumination optical unit 4 which are illuminated in a defined manner can be achieved by a redistribution of the illumination channels.

Further aspects and details of the illumination of the object field 5 and in particular of the entrance pupil of the projection optical unit 10 are described hereinafter.

The projection optical unit 10 can have a homocentric entrance pupil in particular. This entrance pupil can be accessible. It can also be inaccessible.

The entrance pupil of the projection optical unit 10 regularly cannot be exactly illuminated with the second facet mirror 22. In the case of imaging of the projection optical unit 10 which telecentrically images the center of the second facet mirror 22 onto the wafer 13, the aperture rays often do not intersect at a single point. However, it is possible to find an area in which the spacing of the aperture rays that is determined in pairs becomes minimal. This area represents the entrance pupil or an area in real space that is conjugate thereto. In particular, this area exhibits a finite curvature.

It may be the case that the projection optical unit 10 has different positions of the entrance pupil for the tangential beam path and for the sagittal beam path. In this case, an imaging element, in particular an optical component part of the transfer optical unit, should be provided between the second facet mirror 22 and the reticle 7. With the aid of this optical element, the different positions of the tangential entrance pupil and the sagittal entrance pupil can be taken into account.

In the arrangement of the component parts of the illumination optical unit 4 illustrated in FIG. 1, the second facet mirror 22 is arranged in an area conjugate to the entrance pupil of the projection optical unit 10. The first facet mirror 20 is arranged tilted in relation to the object plane 6. The first facet mirror 20 is arranged tilted in relation to an arrangement plane defined by the deflection mirror 19. The first facet mirror 20 is arranged tilted in relation to an arrangement plane defined by the second facet mirror 22.

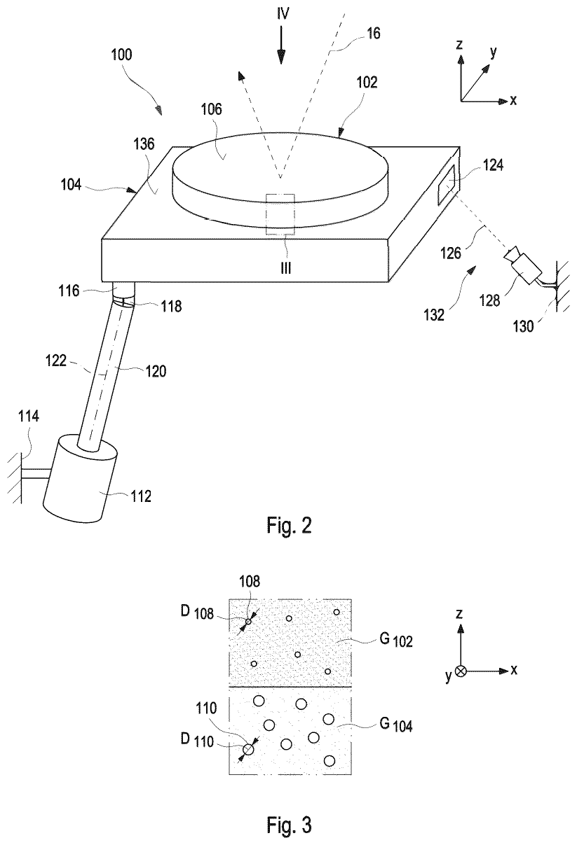

FIG. 2 shows a detail from the lithography apparatus 1 from FIG. 1. An optical component 100 comprising an optical element 102 and a carrying element 104 can be seen.

The optical element 102 can be in particular one of the mirrors M1 to M6 from FIG. 1, or an optical element from any other optics system (e.g. a measuring system for application in the field of lithography). In particular, it could be one of the mirrors from the illumination system 2 from FIG. 1. In principle, the optical element 102 can be a mirror, a lens element, a polarization-optical element, in particular a retarder plate, a polarization filter or a rotation element configured to rotate a polarization direction, a color filter or an optical grating. In the exemplary embodiment according to FIG. 2, the optical element 102 is a mirror.

The optical element 102 comprises an optically effective surface 106. The illumination radiation 16 (see also FIG. 1) or the operating light is reflected at said optically effective surface. The illumination radiation is preferably EUV radiation, that is to say light having a wavelength of between 0.1 and 30 nm.

The optical element 102 is fabricated from a first material, for example ULE, Zerodur, calcium fluoride or quartz glass. The fabrication of the optical element 102 is thus comparatively costly.

The carrying element 104 carries the optical element 102. That should be understood to mean, in particular, that the forces resulting from the gravitational force acting on the optical element 102 are partly or wholly introduced into the carrying element 104 from the optical element 102. Dynamic loads such as, for instance, those resulting from vibrations or other accelerations may be added to the gravitational force.

The carrying element 104 is fabricated from a second material. The second material can be fabricated for example from quartz glass, optical glass, glass ceramic, silicon, SiSiC (silicon carbide) or steel, in particular Invar. Accordingly, the second material is a comparatively cost-effective material, and so the production costs for the optical component 100 overall are reduced.

FIG. 3 shows a detail III from FIG. 2. It can be seen there that the first material G102 differs from the second material G₁₀₄. In particular, the following holds true for the ratio of the densities ρ_{G102}, ρ_{G104} of the first and second materials G₁₀₂, G₁₀₄ (first material G₁₀₂ having the first density ρ_{G102}, second material G₁₀₄ having the second density ρ_{G104}):

$$\frac{{ρ}_{G 102}}{{ρ}_{G 104}} < ( 1 + x ) \qquad ( 1 )$$

$$\frac{{ρ}_{G 102}}{{ρ}_{G 104}} > ( 1 - x ) \qquad ( 2 )$$

$$\frac{{ρ}_{G 104}}{{ρ}_{G 102}} < ( 1 + x ) \qquad ( 3 )$$

$$\frac{{ρ}_{G 104}}{{ρ}_{G 102}} > ( 1 - x ) \qquad ( 4 )$$

where x is: 20%, preferably 10%, and even more preferably 5%. Formulae (1) to (4) above are applicable cumulatively. In other words, the first and second materials are comparable with regard to their density, and so from a mechanical and/or thermal standpoint there are tenable differences between them. Preferably, the ratio of the densities ρ_{G102}, ρ_{G104} of the first and second materials G₁₀₂, G₁₀₄ deviates from 1, from 1.0, from 1.00, from 1.000 or from 1.0000 within the above limits.

By way of example, ULE having a density of 2.21 g/cm³ (at 25° C.) is used as first material G₁₀₂, and a quartz glass having a density of 2.20 g/cm³ (at 25° C.) is used as second material G₁₀₄. Accordingly, the ratio ρ_{G102} to ρ_{G104} is 1.005 and thus lies within the limits defined above.

The first and second materials can differ for example in the proportion and size of inclusions, in particular bubbles 108, 110. As can be seen in FIG. 3, the diameter D₁₁₀ of the bubbles 110 in the material G₁₀₄ is greater than the diameter D₁₀₈ of the bubbles 108 in the material G₁₀₂. Moreover, the materials G₁₀₂ and G₁₀₄ can differ with regard to the proportion, expressed in percent by volume, of the bubbles 108, 110. Furthermore or alternatively, the first and second materials G₁₀₂, G₁₀₄ can differ in a number of further properties: By way of example, mention shall be made below of a refractive index homogeneity; a stress birefringence; an intrinsic polarization birefringence; a transmissivity, particularly at the operating wavelength of the optical component 100; a density or a change in the density in at least one spatial direction; a hardness or a change in the hardness in at least one spatial direction; a slumping property; a roughness; and a resistance to compaction or/and solarization, in particular as a result of the used radiation.

The coefficient of thermal expansion of the first material G₁₀₂ is preferably at least ten times lower than a coefficient of thermal expansion of the material G₁₀₄, specifically at a temperature of the first and second materials G₁₀₂, G₁₀₄ at a mean expected operating temperature, which can lie e.g. in a range of between 22° C. and 32° C.

Returning now to FIG. 2, it can be seen there that the optical component 100 is supported on a carrying frame 114 of the lithography apparatus 1 in a manner manipulatable in space with an actuator 112. For this purpose, the carrying element 104 comprises a mechanical interface 116 (e.g. a stud). A flexure 118 is secured to the interface 116. The flexure 118 connects a pin 120 to the interface 116 in a manner pivotable by two degrees of freedom. The pin 120 is displaced along its longitudinal axis 122 with the aid of the actuator 112 in order to change the position of the optical component 100 or of the optically effective surface 106 in space. The interface 116 could be any other mechanical interface.

Additionally or alternatively, the carrying element 104 can comprise a measurement object 124. In accordance with the exemplary embodiment, the measurement object 124 is a reflector configured to reflect a measurement beam 126. The measurement beam 126 is emitted by an interferometer 128, for example, which is in turn secured to a sensor frame 130. The actual position (position and orientation) of the optically effective surface 106 can be ascertained with the aid of the measurement arrangement 132, comprising the interferometer 128 and the measurement object 124.

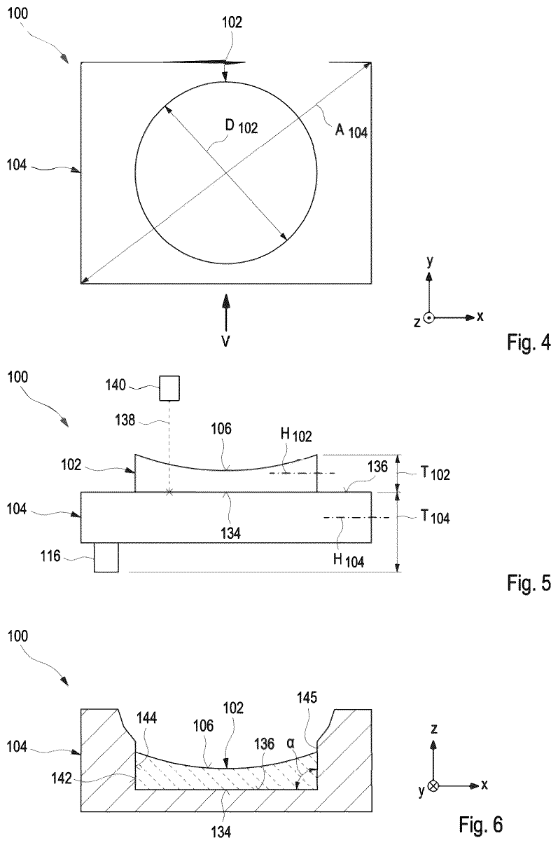

FIG. 4 shows a plan view IV from FIG. 2, specifically counter to the z-direction (vertical direction) as seen in FIG. 2. The vectors x, y describe a horizontal plane that is perpendicular to the vector z. FIG. 5 shows a view V from FIG. 4.

The optical element 102 has a principal extension plane H₁₀₂ (see FIG. 5) and the carrying element 104 has a principal extension plane H₁₀₄ (also see FIG. 5). The principal extension plane is that plane in which the respective component 102, 104 substantially extends. The respective extension in the principal extension plane is greater than in any other plane. In accordance with the exemplary embodiment, the principal extension plane H₁₀₂, H₁₀₄ lies in each case in the xy-plane.

In FIG. 4, the principal extension planes H₁₀₂, H₁₀₄ (not shown) lie one above the other and in each case parallel to the plane of the drawing. In their respective principal extension plane H₁₀₂, H₁₀₄, the optical element 102 and the carrying element 104 each have a maximum extent. Said maximum extent for the optical element 102 is the diameter D₁₀₂ thereof and for the carrying element 104 is the diagonal A₁₀₄ thereof. The diameter D₁₀₂ is less than 90%, preferably less than 80%, and more preferably less than 75%, of the diagonal A₁₀₄.

Perpendicular to the principal extension planes H₁₀₂, H₁₀₄, the optical element 102 and the carrying element 104 each have a maximum thickness. In accordance with the exemplary embodiment, the thickness specifies the maximum extent in the z-direction. The thickness T₁₀₂ (maximum thickness) of the optical element 102 shown in FIG. 5 is with preference less than 90%, preferably less than 80%, even more preferably less than 75%, of the maximum thickness T₁₀₄ of the carrying element 104. As can likewise be seen in FIG. 5, the optical element 102 is in whole-area contact with the surface 136 of the carrying element 4 through the rear side 134 of the optical element, i.e. that side which faces away from the optically effective surface 106. The surface 136 (see also FIG. 2) of the carrying element 102 is that surface of the carrying element 104 which faces the optical element 102. Instead of the whole-area contact over 100% of the rear side 134 as shown, provision could also be made for (only) at least 50%, preferably at least 75%, and even more preferably at least 90%, of the rear side 134 of the optical element 102 to be in contact with the carrying element 104. By way of example, ribs could be shaped on the surface 136, said ribs correspondingly reducing the contact between the rear side 134 and the surface 136.

In accordance with the exemplary embodiment, the optical element 102 and the carrying element 104 are formed integrally, wherein they are shaped in a manner materially bonded to one another in accordance with the exemplary embodiment according to FIGS. 2 to 5. The materially bonded engagement is produced by the optical element 102 and the carrying element 104 preferably being fused together, adhesively bonded to one another or wrung on one another. Preference is given to a thermal connection in which high temperatures above the glass transition temperature are set in an environment of the parting surface (rear side 134, surface 136), with the result that the optical element 102 and the carrying element 104 join together there. During the cooling process, frozen-in thermal stresses are preferably largely avoided, which is achieved for example by complying with a predefined cooling curve in which a maximum value for the temporal temperature gradient is not exceeded particularly at a high temperature. Subsequent annealing steps can alternatively relieve such stresses. In particular, provision can also be made for welding at the interface to be provided. By way of example, a laser beam 138 from a laser source 140 can be used at the interface to fuse the surfaces 134, 136 together.

In this respect, FIG. 15 illustrates a flow diagram of one exemplary embodiment of a method for producing the component 100, for example as described in FIGS. 2 to 5.

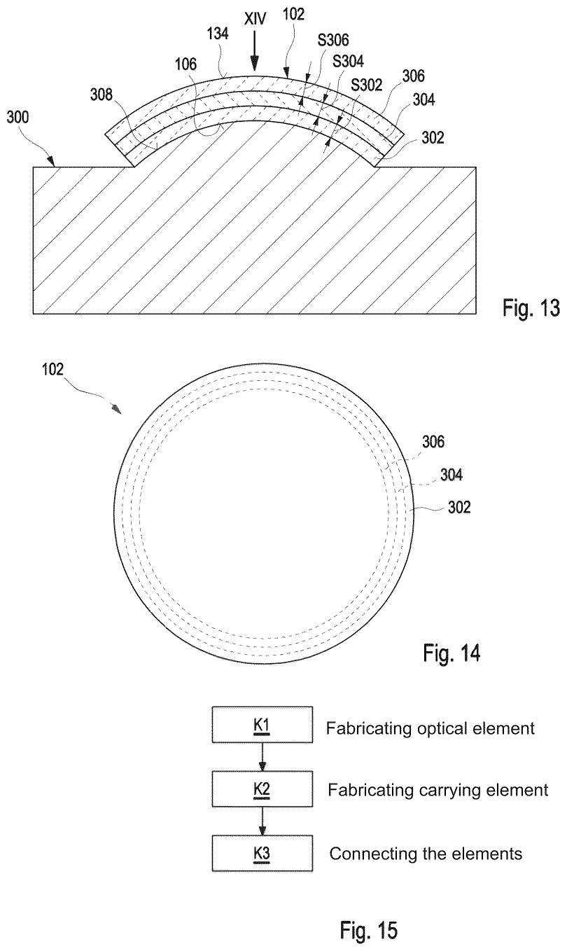

In a step K1, the optical element 102 comprising the material G₁₀₂ is fabricated. In a step K2, the carrying element 104 comprising the material G₁₀₄ is fabricated. By way of example, step K2 can take place before, after or at the same time as step K1. In a step K3, the optical element 102 and the carrying element 104 are connected to one another (for example by being adhesively bonded, wrung on one another, subjected to laser treatment or fused in some other manner) so that the carrying element 104 carries the optical element 102. This includes the possibility of the optical element 102 and the carrying element 104 being integrally primary formed (for instance by casting or in a slumping method, also cf. the explanations below in regard to FIGS. 13 and 14) and thus already being connected to one another in a common production process. Furthermore, firstly the carrying element 104 can be produced and thereupon the optical element 102 can be primary formed and thereby simultaneously connected to the carrying element 104.

Moreover, there is the possibility of the carrying element 104 being produced on the optical element 102 by primary forming and thereby being connected to the optical element.

In particular, the optical element 102 and/or the carrying element 104 are/is subjected to material-ablating processing in order to produce the optical component 100 in a suitable manner for its purpose of use, in particular in a projection exposure apparatus 1. An ablation method can comprise milling or polishing, in particular. Depending on the processing quality to be achieved, the ablation rate, i.e. the material volume ablated per unit time, for example in mm3/h, is varied to a greater or lesser extent. For the high-quality optical element 102, the ablation rate at which the first material G₁₀₂ is ablated varies over the entire material-ablating processing process preferably by more than 20%, more preferably by more than 30%, even more preferably by more than 50%. As a result, the processing process can be highly accurately adapted to the respective structure, in particular crystalline structure, of the first material G₁₀₂. By contrast, the ablation rate in regard to the second material G₁₀₄ (once again over the entire material-ablating processing process) varies by less than 50%, preferably by less than 30%, and even more preferably by less than 20%. Highly accurate processing of the second material G₁₀₄ is preferably not provided, in order to reduce the outlay.

FIG. 6 shows a sectional view of an optical component 100 in accordance with a further embodiment in which the optical element 102 is embedded in the carrying element 104 such that, both by its rear side 134 and by a circumferential surface 142, the optical element bears against a corresponding surface 136 and, respectively, corresponding side surfaces 144 of the carrying element 104 and/or is secured there. In particular, the surface 136 and the side surfaces 144 can define a pot-like depression 145, into which the optical element 102 is fitted. The circumferential surface 142 can be at an angle α of 90° with respect to the rear side 134. However, other angles different from 90° are also feasible. By way of example, the angle α can be between 90° and 110°. This can facilitate fitting the optical element 102 into the carrying element 104 or into the corresponding pot-like opening.

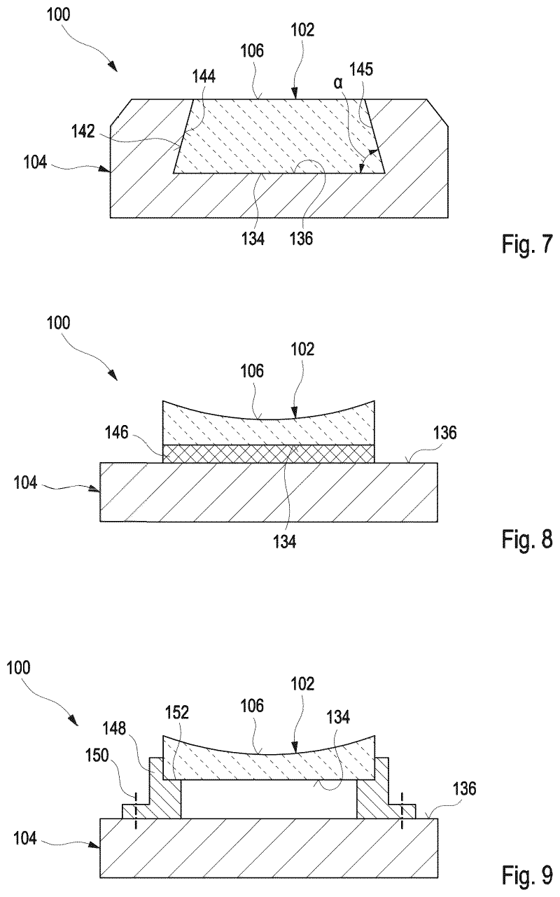

FIG. 7 shows a further example of an optical element 100. In this embodiment shown in section, the angle α spanned between the rear side 134 and the circumferential surface 142 is less than 90°, for example between 70° and 90°, in particular between 70° and 85°. In this embodiment, the optical element 102 is cast into the carrying element 106 or into the pot-shaped opening formed by the carrying element 106.

In the sectional view of an optical element 100 in accordance with a further embodiment as shown in FIG. 8, the optical element 102 is adhesively bonded to the carrying element 104 with the aid of an adhesive 146. In particular, in that case the rear side 134 of the optical element 102 is adhesively bonded to the surface 136 of the carrying element 104.

Accordingly, FIG. 8 shows one example of indirect securing of the optical element 102 to the carrying element 104. This is in contrast to the exemplary embodiments according to FIGS. 2 to 7, in which the optical element 102 is preferably directly secured to the carrying element 104, in particular in a materially bonded manner.

FIG. 9 also shows one embodiment of indirect securing, wherein the optical element 102 is secured to the carrying element 104 with the aid of an intermediate mount 148. The intermediate mount 148 can be produced from metal, for example Invar. The intermediate mount 148 holds the optical element 102 at a distance from the carrying element 104. The intermediate mount 148 can be secured to the carrying element 104 for example with screws 150 or other securing elements. The optical element 102 can be adhesively bonded for example onto holding elements, in particular small feet 152, of the intermediate mount 148, although other securing possibilities are feasible.

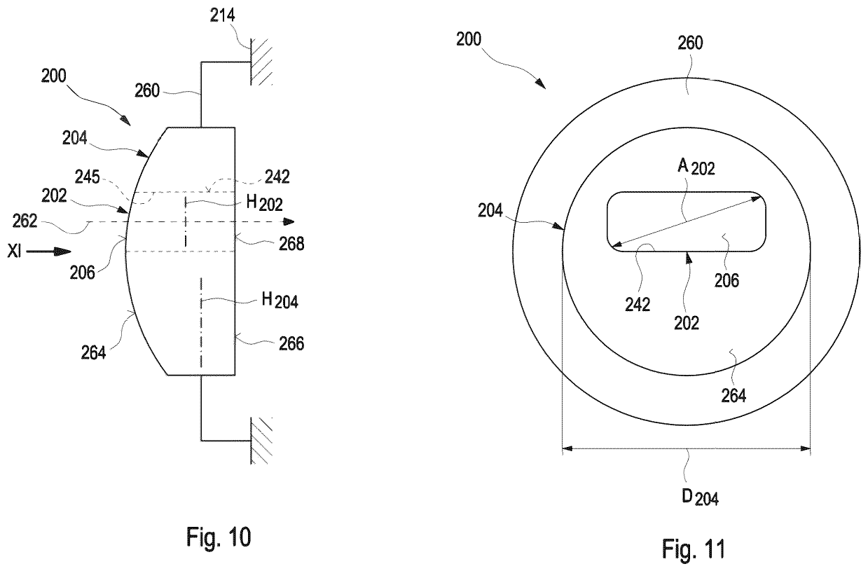

FIG. 10 shows one embodiment of an optical component 200 in which a lens element is provided as optical element 202. FIG. 10 shows the optical component 200 here in a side view.

The optical element 202 is integrated in a carrying element 204. The carrying element 204 is secured to a carrying frame 214 of a DUV lithography apparatus, not illustrated in more specific detail. For this purpose, a mount 260 can be provided, for example, which connects the carrying element 204 to the carrying frame 214.

Operating or used light 262 is incident on an optically effective surface 206 of the optical element 202 and passes through the element on its way for instance to a wafer (not illustrated).

The optical element 202, at its circumferential surface 242, is formed integrally with the carrying element 204. The circumferential surface 242 describes a ring-shapedly closed contour, for example, as can be discerned in FIG. 11. The contour can be formed for example so as to be circular, oval, rectangular with rounded corners, trapezoidal or in any other suitable fashion. All that is crucial for the geometry of the circumferential surface 242 is that imaging with the aid of the optical element 202 succeeds with sufficient quality. At its circumferential surface 242, the optical element 202 is connected, in particular in a materially bonded manner, to the carrying element 204. This can be realized in particular by fusing the optical element 202 to the carrying element 204.

The optical component 200 or the optical element 202 and the carrying element 204 can jointly define a disk-shaped geometry. The carrying element is curved on at least one side in accordance with the exemplary embodiment, the side 264 also containing the optically effective surface 206 in the exemplary embodiment. The opposite side 266 can be embodied so as to be straight.

In principle, the optical component 200 or the sides (side surfaces) 264, 266 thereof can define a biconvex, planoconvex, concavo-convex, convexo-concave, planoconcave or biconcave shape. Preferably, the side 264 or the corresponding surface is formed continuously, that is to say in particular without a step, with the region of the optically effective surface 206. The light exit side 268 of the optical element 202 is also preferably formed continuously, that is to say in particular without a step, with the surrounding region of the side 266.

FIG. 10 illustrates the principal extension planes H202, H204 of the optical element 202 and of the carrying element 204 respectively (see FIG. 10). A diagonal A202 in FIG. 11 corresponds to the maximum extent of the optical element 202 in the principal extension plane H202 thereof. The maximum extent of the carrying element 204 in the principal extension plane H204 thereof corresponds to the diameter D204 thereof (see FIG. 11). The maximum extent A202 is less than 90% of the maximum extent D204, preferably less than 80%, and even more preferably less than 75%. This value is 85% in the exemplary embodiment according to FIGS. 10 and 11.

In particular, it is thus also possible to produce lens element systems which comprise regions (lens element 202) with a stringent refractive index homogeneity requirement, with low stress birefringence, with a transmissivity for the operating wavelength that is above a predetermined limit, and/or with a high robustness vis-à-vis irradiation at the operating wavelength (for example with regard to compaction or solarization) and/or are characterized by a particular, for instance low or predefined oriented intrinsic birefringence in the optically traversed volume and relaxed requirements outside (in the region of the carrying element 204) that. Especially catadioptric designs with geometric beam splitting use near-field lens element systems with an off-axis footprint, while a rotationally symmetrical lens element body (lens element 202) is often installed for the purpose of mechatronic compatibility and symmetrical mount technology.

The joining together or insertion (see FIGS. 1 to 5, 8, 9 or FIGS. 6, 7, 10 and 11) of the optical element 102, 202 with or respectively into the carrying element 104, 204 may lead to deformations, thus necessitating subsequent processing steps for adjusting the final fit. Alternatively, it is possible to carry out all processing steps including coating before the insertion of the optical element 102, 202 into the carrying element 104, 204 or before the joining together and to compensate for the deformation owing to the joining process by subsequent locally variable material compaction by electron or ion irradiation in a method such as, for instance, ICE-T. Such methods are described for example in the documents DE 10 2011 084 117 A1, DE 10 2015 201 141 A1, DE 10 2012 223 669 A1, DE 10 2014 225 197 A1, WO 2017/148577 A1 and DE 10 2015 223 795 A1.

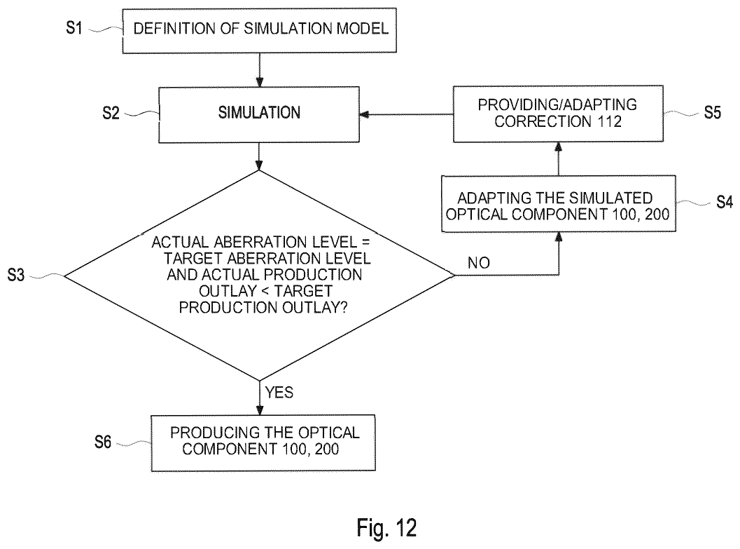

One embodiment of a method for producing an optical component 100, 200 is explained in greater detail below with reference to FIG. 12.

In a first step S1, a simulation model comprising the optical component 100, 200 is defined. This involves firstly selecting relevant use scenarios. These scenarios consist of one or more illumination distributions and associated (dominant) mask structures that each define a diffraction distribution downstream of reticle 7 (see FIG. 1). On the basis of a predefined source power and the transmissivity of all optical elements—in particular those of the optical elements 102, 202—in the light path 16 (see FIG. 1), the locally variable irradiation intensity is ascertained for the relevant optical element 102, 202. The absorption behavior of the optical element 102, 202, which may if appropriate be dependent on the angle of incidence, is taken as a basis for ascertaining what power is locally absorbed in each case.

In a second step S2, various designs of the optical component 100, 200, as illustrated with reference to FIGS. 5 to 11, for instance, can then be mechanically and/or thermally modeled. In this case, taking into account the irradiation history, for example, a temperature distribution is ascertained in each variant, which can be done using a finite element simulation, for example. Together with assumptions concerning coefficients of thermal expansion of the materials G102, G104 involved, a resulting refractive index change and/or surface deformation are/is subsequently calculated. With the aid of optical ray tracing, the resulting aberration pattern or aberration level is determined for this purpose. The aberration level can be defined for example as an RMS (“root mean square”) value of the wavefront or as a maximum of all decomposition coefficients of the wavefront according to Zernike functions up to order 100.

A production outlay for the optical component 100, 200 can also be ascertained in the simulation in accordance with step S2. Said production outlay can comprise for example machine hours (e.g. on a mill), material costs, etc.

In a step S3, for example, the simulated actual aberration level (in the present case also “actual property” or this involves one of the “properties of the optical component”) is compared with a target aberration level (in the present case also “target property”). In particular, a simulated actual RMS value of the wavefront can be compared with a target RMS value of the wavefront. Furthermore, a simulated actual production outlay can be compared with a target production outlay.

If either the simulated actual property does not correspond to the desired target property (for instance the simulated actual RMS value lies above a target RMS value) or the actual production outlay lies above the target production outlay, then steps S4 and S5 take place. Steps S4 and S5 can be carried out in each case or alternatively.

In accordance with step S4, the simulation model is adapted. In particular, this involves modifying a dimension of the optical elements 102, 202 and/or of the carrying elements 104, 204.

Additionally or alternatively, for example, the first and/or second material G102, G104 can also be altered. In particular, if a desired target aberration is not yet attained, the first material G102 can be improved. By way of example, it is possible to use a material with an improved refractive index homogeneity, with a smaller proportion and/or a smaller size of inclusions, a lower stress birefringence or a lower loss of contrast, a specific intrinsic stress birefringence, a higher transmissivity, a higher density or hardness or a smaller change thereof in at least one spatial direction, an improved slumping property, less compaction or solarization. Conversely, if the actual aberration is better than the target aberration, it is also possible to reduce the optical quality of the second material in order to decrease the production outlay and thus to fulfill a production budget.

As an example, it is thus possible to carry out a series of refining fabrication steps such as, for instance, prepolishing toward a required surface quality, for example with regard to roughness, only for the optical element 102, 202 or the first material G102, but not for the carrying element 104, 204. As a result, smaller tools can be used during production, the processing time decreases and smaller masses need to be handled during transporting and clamping processes. This reduces the technical outlay and often the reject rate.

Instead of adapting the simulation model in accordance with step S4, it may suffice to provide suitable correction, to adapt the actual property to the target property. The addition of corresponding a correction mechanism can be constituted such that it only insignificantly increases the production outlay. The correction mechanism can include for example further optical elements that are manipulatable in rigid body degrees of freedom, for instance, in the beam path upstream or downstream of the optical element 102, 202. Furthermore, thermally influenceable optics parts, deformable mirrors, Alvarez elements, etc., can be provided in the beam path upstream and/or downstream of the optical element 102, 202. This serves in particular for correcting residual optical aberrations of the simulated projection exposure apparatus 1 (or else of some other optical system). One example of such a correction mechanism is the actuator 112 (see FIG. 2) configured to manipulate the position of the optical element 102 in space (see FIG. 2).

If the actual aberration level corresponds to the target aberration level (or lies below it) and if the actual production outlay lies below the target production outlay, that is to say in the budget, then in a step S6 (see FIG. 12) the optical component 100, 102 is produced in accordance with the simulated features.

FIG. 13 illustrates a method step during the production of the optical element 102 in a slumping method. FIG. 13 shows a mold tool 300 in section, and FIG. 14 shows a plan view XIV from FIG. 13.

The production of the optical element 102 in the slumping method corresponds for example to method step K1 shown in FIG. 15. For this purpose, a plurality of layers 302 to 306 having layer thicknesses S302 to S306 composed of a glass substrate, for example, are constructed on the mold tool 300. The still soft layers 302 to 306 assume the shape of an outer (convex) contour 308 of the mold tool 300, with the result that the optically effective surface 106 is produced with the desired contour. The three layers 302 to 306 shown are purely by way of example. A multiplicity of such layers are produced in reality.

The carrying element 104 can likewise be produced in a (costly) slumping method. Alternatively, the carrying element 104 can be produced without application of a slumping method, for instance with a material-ablating method, such as milling and/or polishing, for example, from a solid material.

However, if the optical element 102 and the carrying element 104 are produced in a slumping method, this is preferably done so that the actual layer thickness attained in each case (for example the layer thicknesses S302 to S306) in the first material G102 (of the optical element 102) deviates maximally or on average to a lesser extent from the sought target layer thickness (defined for instance in a CAD model of the optical element 102) than is the case for the layer thicknesses (not illustrated) of the second material G104 (of the carrying element 104). In particular, an actual layer thickness of the first material G102 can be less than 10%, preferably less than 20% or more preferably less than 50% closer to the respective target layer thickness than in the case of the second material G104.

Although the present invention has been described on the basis of exemplary embodiments, it is modifiable in diverse ways. From the disclosure given, those skilled in the art will not only understand the present invention and its attendant advantages, but will also find apparent various changes and modifications to the structures and methods disclosed. The applicant seeks, therefore, to cover all such changes and modifications as fall within the spirit and scope of the invention, as defined by the appended claims, and equivalents thereof.

### LIST OF REFERENCE SIGNS

1 Projection exposure apparatus
2 Illumination system
3 Light source
4 Illumination optical unit
5 Object field
6 Object plane
7 Reticle
8 Reticle holder
9 Reticle displacement drive
Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Optical component
102 Optical element
104 Carrying element
106 Optically effective surface
108, 110 Bubbles
112 Actuator
114 Carrying frame
116 Interface
118 Flexure
120 Pin
122 Longitudinal axis
124 Measurement object
126 Measurement beam
128 Interferometer
130 Sensor frame
132 Measurement arrangement
134 Rear side
136 Surface
138 Laser
140 Laser source
142 Circumferential surface
144 Side surface
145 Depression
146 Adhesive
148 Intermediate mount
150 Screw
152 Small foot
200 Optical component
202 Optical element
204 Carrying element
206 Optically effective surface
214 Carrying frame
242 Circumferential surface
245 Through opening
260 Mount
262 Operating light
264, 266 Sides
268 Exit surface
300 Mold tool
302 Layer
304, 306 Layers
308 Contour
α Angle
A₁₀₄ Diagonal
A₂₀₂ Diagonal
D₁₀₂ Dimension
D₂₀₄ Dimension
H₁₀₂ Principal extension plane
H₁₀₄ Principal extension plane
H₂₀₂ Principal extension plane
H₂₀₄ Principal extension plane
K1 to K3 Method steps
M1 Mirror
M2 Mirror
M3 Mirror
M4 Mirror
M5 Mirror
M6 Mirror
S1 to S6 Method steps
S₃₀₂ Layer thickness
S₃₀₄ Layer thickness
S₃₀₆ Layer thickness
T₁₀₂ Thickness
T₁₀₄ Thickness
x, y, z Spatial directions

What is claimed is:

1. An optical component for a lithography apparatus, comprising
an optical element, which is fabricated from a first material and comprises an optically effective surface; and
a carrying element, which is fabricated from a second material and carries the optical element, wherein the second material differs from the first material and a ratio of the densities of the first and second materials deviates from 1 by less than 20%;
wherein the optical element and the carrying element each have a principal extension plane having a respective maximum extent, wherein the maximum extent of the optical element is less than 90% of the maximum extent of the carrying element; and
wherein the optical element comprises a side facing away from the optically effective surface, the side comprises a side surface, and at least 50% of the side surface of the optical element is in contact with the carrying element.

2. The optical component as claimed in claim 1, wherein the optical element and the carrying element each comprise a respective maximum thickness perpendicular to the principal extension plane, and wherein the maximum thickness of the optical element is less than 90% of the maximum thickness of the carrying element.

3. The optical component as claimed in claim 1, wherein at least 75% of the side surface of the optical element is in whole-area contact with the carrying element.

4. The optical component as claimed in claim 1, wherein the optical element is accommodated in a depression or in a through opening in the carrying element and/or wherein a material boundary between the first and second materials runs partly or completely in a direction perpendicular to the principal extension plane of the optical element.

5. The optical component as claimed in claim 1, wherein the optical element and the carrying element are formed integrally and/or wherein the optical element and the carrying element are secured to one another in a force-locking, materially bonded and/or interlocking manner.

6. The optical component as claimed in claim 1, wherein the optical element and the carrying element are fused together, adhesively bonded to one another or wrung on one another.

7. The optical component as claimed in claim 1, wherein the first and the second materials differ in at least one of the following properties:
a refractive index homogeneity;
a proportion and/or a size of inclusions;
a stress birefringence;
an intrinsic polarization birefringence;
a transmissivity of the optical element;
a density and/or a change in the density in at least one spatial direction;
a slumping property;
a roughness; and
a resistance to compaction and/or solarization.

8. The optical component as claimed in claim 1, wherein at a projected mean operating temperature, a coefficient of thermal expansion of the first material is at least ten times lower than a coefficient of thermal expansion of the second material.

9. The optical component as claimed in claim 1, wherein the carrying element comprises at least one of the following component parts:
a mechanical interface configured to secure the carrying element to a carrying frame of a lithography apparatus and/or configured to secure an actuator to the carrying frame; and/or
a measurement object configured to establish a position of the carrying element with an associated measuring device.

10. The optical component as claimed in claim 1, wherein the optical element is a mirror, a lens element, a polarization-optical element, a polarization filter or a rotation element configured to rotate a polarization direction, a color filter, and/or an optical grating.

11. The optical component as claimed in claim 1, wherein the first material comprises ultralow expansion material, Zerodur, calcium fluoride and/or quartz glass, and/or the second material comprises quartz glass, optical glass, glass ceramic, silicon, SiSiC or steel.

12. A projection lens comprising an optical component as claimed in claim 1.

13. A projection lens as claimed in claim 12 and configured as a catadioptric projection lens or configured with a pure mirror system.

14. A lithography apparatus configured as an extreme ultraviolet or deep ultraviolet lithography apparatus and comprising an optical component as claimed in claim 1.

15. A method for producing an optical component as claimed in claim 1, comprising:
a) simulating properties of the optical component in operation;
b) adapting at least one of the properties in accordance with the simulation; and
c) producing the optical component with the adapted property.

16. The method as claimed in claim 15, wherein:
the properties of the optical component in operation are simulated in accordance with said simulating in a first simulation;
simulating a production outlay for producing the optical component in a second simulation; and
adapting the at least one property in accordance with said adapting in accordance with the first and the second simulations.

17. The method as claimed in claim 15, wherein:
the properties simulated in accordance with said simulating comprise an optical property of the optically effective surface; and/or
adapting the at least one property in accordance with said adapting comprises adapting a dimension of the optical element and/or of the carrying element and/or adapting the first and/or the second material; and/or
said adapting of the at least one property of the optical element comprises ascertaining a correction element, wherein the correction element is provided outside the optical component.

18. A method for producing an optical component for a lithography apparatus, comprising:
a) fabricating an optical element from a first material having a first density and comprising an optically effective surface;
b) fabricating a carrying element from a second material having a second density, wherein the second material differs from the first material and a ratio of the densities of the first and the second materials deviates from 1 by less than 20%; and
c) connecting the optical element to the carrying element such that the carrying element carries the optical element,
wherein the optical element and the carrying element each have a respective principal extension plane having a respective maximum extent, wherein the maximum extent of the optical element is less than 90% of the maximum extent of the carrying element.

19. The method as claimed in claim 18, wherein, in said fabricating of the optical element, a variation of an ablation rate at which the first material is ablated is greater than 20% and/or wherein, in said fabricating of the carrying element, a variation of an ablation rate at which the second material is ablated is less than or equal to 20%.

20. The method as claimed in claim 18, wherein said fabricating of the optical element and/or said fabricating of the carrying element comprises application of a slumping method.

21. The method as claimed in claim 20, wherein, in the slumping method, a maximum or a mean deviation of an actual layer thickness from a target layer thickness is smaller for the first material than for the second material.
